(19) United States
(12) Patent Application Publication
(10) Pub. No.: US 2016/0254775 A1
(43) Pub. Date: Sep. 1, 2016

(54) METHODS AND APPARATUS FOR STRUCTURALLY SUPPORTING GEOMETRICALLY COMPLEX SOLAR MODULES USING A RIGID SUBSTRATE AND POINT SUPPORT CONNECTIONS

(71) Applicant: Pvilion, Inc., Brooklyn, NY (US)

(72) Inventors: Todd Dalland, New, NY (US); Robert Lerner, Port Washington, NY (US); Colin Touhey, Brooklyn, NY (US)

(21) Appl. No.: 14/872,905

(22) Filed: Oct. 1, 2015

Related U.S. Application Data
(60) Provisional application No. 62/058,332, filed on Oct. 1, 2014.

(51) Int. Cl. H02S 20/20; H01L 31/0392; H02S 30/10

(52) U.S. Cl. CPC H02S 20/20; H02S 30/10; H01L 31/03926

(57) ABSTRACT

Geometrically complex solar panels are disclosed. The geometrically complex solar panels disclosed herein can take advantage of the flexibility of monocrystalline solar cells while enhancing security and functionality of the cells and to widen the design limits faced by architects and builders in planning for the use of solar energy panels by custom creating a pre-formed rigid shell mount that fixes and stabilizes the cell arrays in the desired form

### CROSS-REFERENCE TO RELATED APPLICATION

This application claims the benefit of U.S. Provisional Patent Application No. 62/058,332, entitled “METHODS AND APPARATUS FOR STRUCTURALLY SUPPORTING GEOMETRICALLY COMPLEX SOLAR MODULES USING A RIGID SUBSTRATE AND POINT SUPPORT CONNECTIONS,” filed Oct. 1, 2014, the disclosure of which is incorporated by reference herein in its entirety.

### BACKGROUND OF THE DISCLOSURE

Photovoltaic Solar panels, whether made using high efficiency monocrystalline silicon cells or polycrystalline cells (15% to 20% efficiency) or lower efficiency thin film cells such as CIGS (10% to 12% efficiency), CAD-TEL (10% to 12% efficiency) or amorphous silicon (3% to 5% efficiency), have been mounted on building roofs and facades for the purpose of converting solar energy into useful electric current.

The basic assembly component of a typical modern photovoltaic solar panel is an either 5×5″ or 6×6″ crystalline photovoltaic cell. Examples of crystalline photovoltaic cells are shown in FIG. 1. These cells are generally encased in glass with metal frames to form rigid solar panels. To mount rigid solar panels, installers have used varieties of mounting systems generally called “racking systems,” which include metal frames, mechanical clips, braces, footings, and ballasts. Over the years, these systems have garnered extensive criticism for their lack of aesthetics.

Historically, solar panels made using high efficiency polycrystalline or monocrystalline type photovoltaic cells have been completely rigid and available in rectangular formats several feet long made of heavy glass laminations with metal frames. An example of such a rigid solar panel is shown in FIG. 2. Rigid panels, because of their lack of flexibility, generally limit architects and builders in their design choices to heavy, planar rectangles several feet long. On the other hand, flexible lightweight thin film panels have found markets where flexibility and geometrical complexity was essential. Flexible lightweight thin film panels are lighter, more flexible, and require no metal frame, but cost more per watt generated and are significantly less efficient than rigid solar panels using high efficiency polycrystalline or monocrystalline type photovoltaic cells. Examples of flexible lightweight thin film solar panels are shown in FIGS. 3A and 3B.

Solar panels made using glass and poly- or monocrystalline silicon are generally shaped as rectangles several feet long are mounted in rectangular or square arrays which consist of rows of panels which are wired linearly in series or parallel configurations. Thus, most installations of multiple panels have been a fractal of the individual panel, i.e., a larger rectangle. When any one panel in a row is shaded, its entire row can be rendered useless if wired in series. If wired in parallel, the voltage will drop to the level of the shaded panel. Either event is undesirable. Each of these individual solar panels is made using multiple columns and rows of fragile mono-crystalline cells or poly-crystalline cells.

### SUMMARY OF THE DISCLOSURE

Methods and apparatus for structurally supporting geometrically complex solar modules using a rigid substrate and point support connections are disclosed. The systems and methods disclosed herein may include reshaping and/or arranging photovoltaic cells, significantly reducing the size of these components and re-configuring them into new forms and shapes and dimensions, wiring them together, adding junction boxes and creating the ability to custom form high efficiency solar panels with a vastly expanded opportunity to create complex new forms. The photovoltaic cells are preferably monocrystalline cells, but use of other types of photovoltaic cells is explicitly contemplated. High efficiency solar panels may thereby be fit onto complex surfaces and forms in a much more efficient manner that was previously possible.

High efficiency, flexible solar panels with very high aspect ratios (e.g., up to or beyond ˜1″×20′) can be created by this method that can be mounted onto complex surfaces. Thus, while it has traditionally been difficult to place heavy, rigid, several foot long solar panels onto surfaces that were irregular in plan (pointed areas of triangular shapes, for example) or complex (spherical, ellipsoidal, pseudospherical, cylindrical, conical, conoidal, hyperbolic parabolic, hyperboloidal) such installations may now be possible. With the systems and methods disclosed herein, solar panels can be shaped to fit and conform to irregular areas and surfaces with improved area coverage.

The geometrically complex solar panels disclosed herein can take advantage of the flexibility of monocrystalline solar cells while enhancing security and functionality of the cells and to widen the design limits faced by architects and builders in planning for the use of solar energy panels by custom creating a pre-formed rigid shell mount that fixes and stabilizes the cell arrays in the desired form.

In some embodiments, a geometrically complex solar module includes a rigid shell including a mounting surface having a curvature that is curved in at least one dimension and a flexible solar module including flexible solar cells, which may be monocrystalline solar cells. The flexible solar module can be coupled to and follow the curvature of the mounting surface. The rigid shell is composed of a conformable material, such as aluminum, steel, acrylic, polycarbonate, wood, concrete, or Plexiglas™, for example and may include a number of holes extending through the mounting surface. The flexible solar cells may be encased in ETFE.

In some embodiments, a mounting system for geometrically complex solar panels includes a mounting member, including a base plate with at least two base apertures and a post extending obliquely from an area of the base plate located between the two base apertures. The post can include a post aperture at a distal end. The mounting system can also include a rod-coupled at a first end to the post aperture and a lug plate coupled to a second end of the rod, opposite the first end. The rod may be length adjustable and rotatably or non-rotatably coupled to the post aperture. The lug plate can be attached to the rigid shell of a geometrically complex solar module, and the mounting member can mount the mounting system on an installation surface.

### BRIEF DESCRIPTION OF THE DRAWINGS

The above and other aspects of the invention, its nature, and various features will become more apparent upon consideration of the following detailed description, taken in conjunction with the accompanying drawings, in which like reference characters refer to like parts throughout, and in which:

FIG. 1 depicts a perspective view of several photovoltaic cells, in accordance with various embodiments;

FIG. 2 depicts a perspective view of photovoltaic cells arranged in a prior art rigid solar panel;

FIGS. 3A and 3B depict perspective views of prior art flexible solar panels;

FIGS. 4A-40 depict exemplary views of various topologies and surfaces for geometrically complex solar panels, in accordance with some embodiments;

FIG. 5A depicts a perspective view of a geometrically complex solar panel, in accordance with some embodiments;

FIG. 5B depicts a front elevation view of a geometrically complex solar panel, in accordance with some embodiments;

FIGS. 6A and 6B depict schematic and perspective views of point connectors for geometrically complex solar panels, in accordance with some embodiments;

FIGS. 7A and 7B depicts schematic and perspective views of point connections for geometrically complex solar panels, in accordance with some embodiments; and

FIGS. 8A and 8B depict schematic and elevation views of geometrically complex solar panel installations, in accordance with some embodiments;

FIGS. 9A-9C depict various views of assembly components for a decorated geometrically complex solar panel installation, in accordance with some embodiments; and

FIGS. 10A and 10B front and back views of perforated geometrically complex solar panels, in accordance with some embodiments.

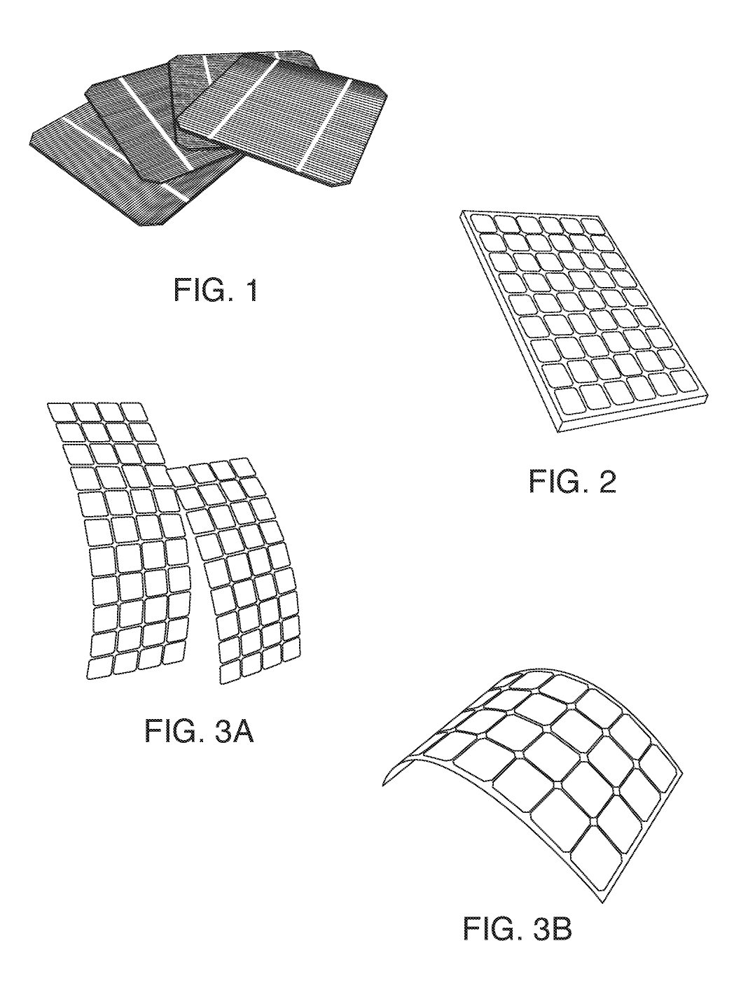

### DETAILED DESCRIPTION OF THE DISCLOSURE

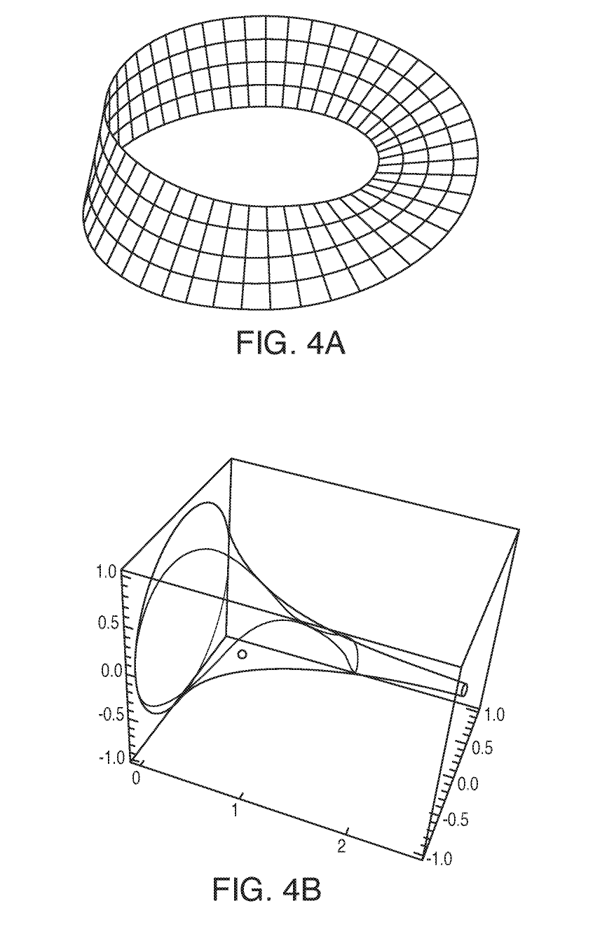

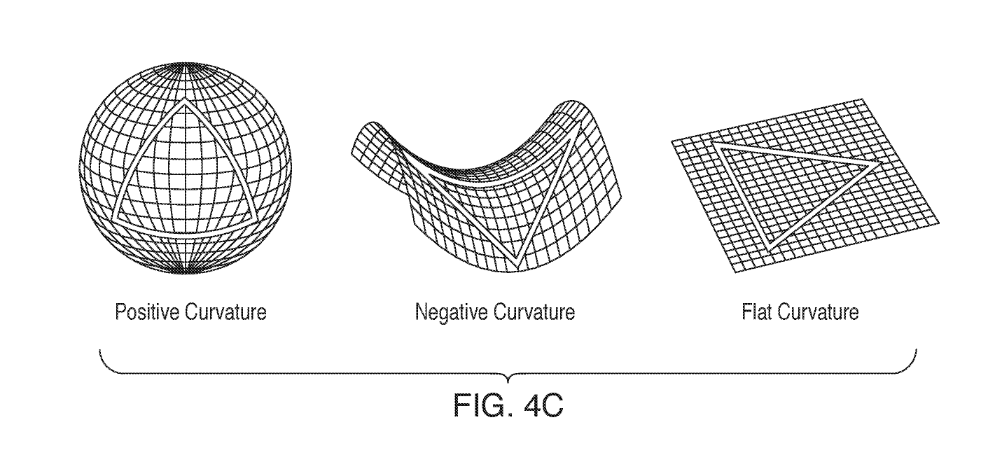

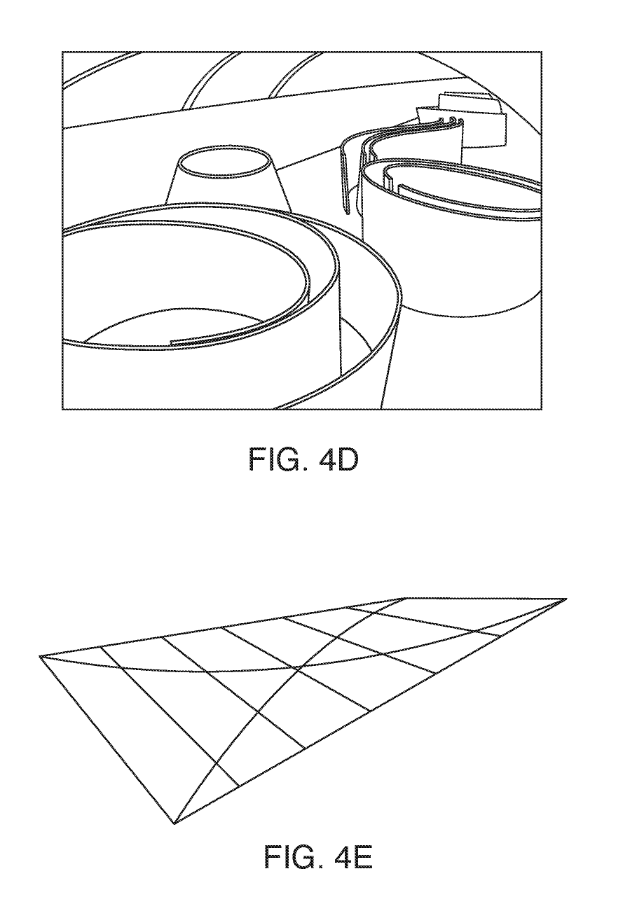

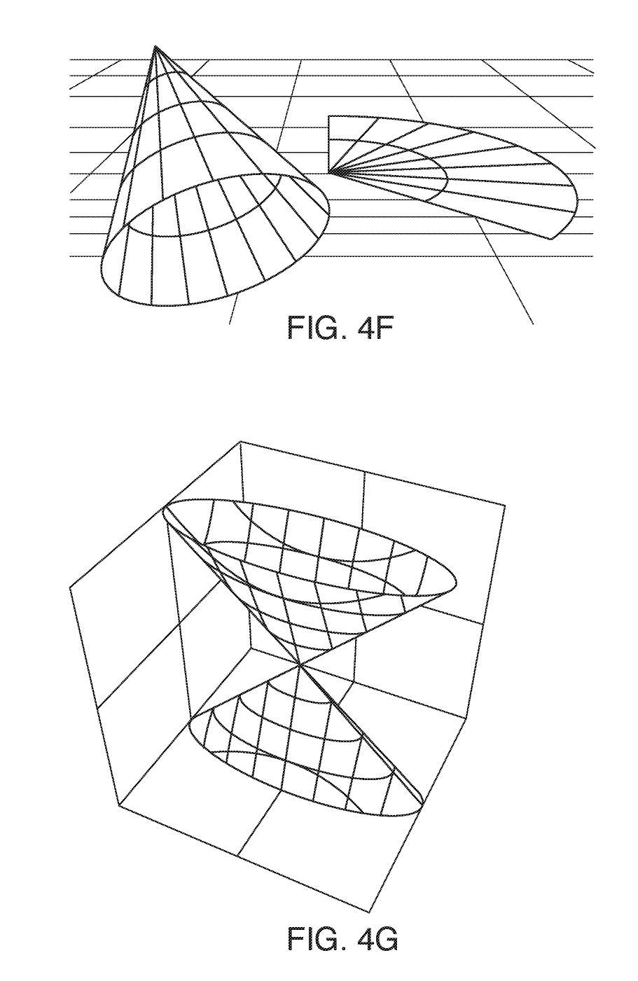

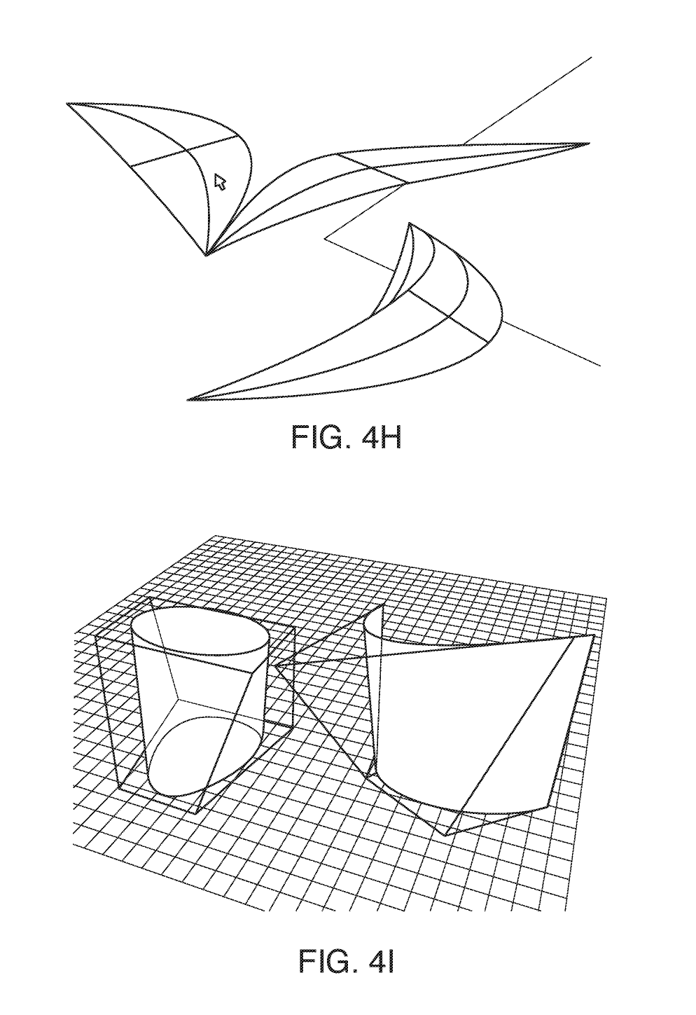

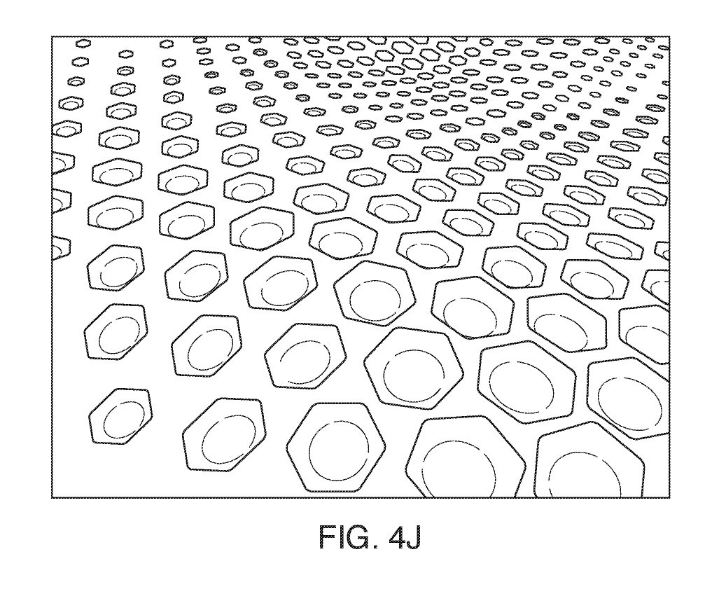

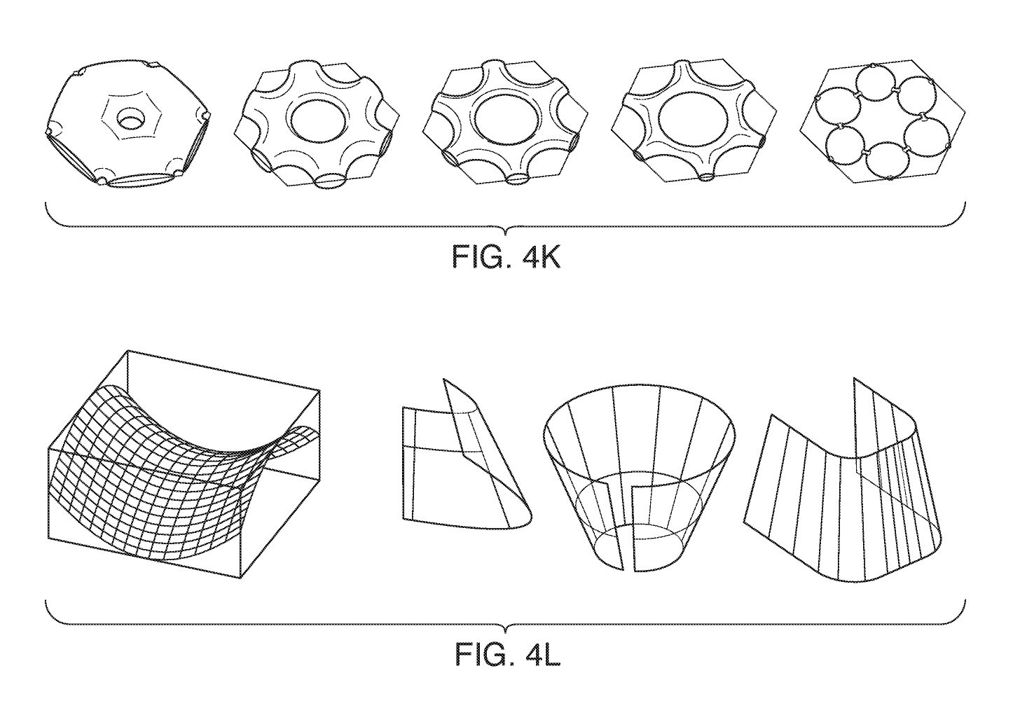

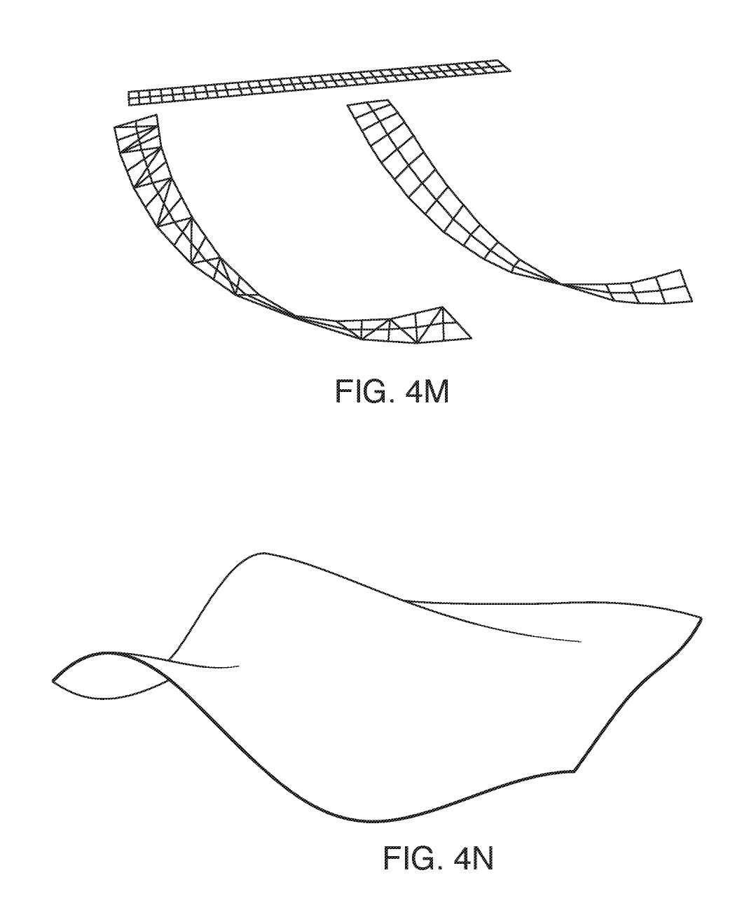

According to some embodiments, the geometrically complex solar panels disclosed herein may include a custom manufactured rigid shell that can serve as a platform for flexible solar cells, which are preferably monocrystalline, though use other types of flexible solar cells (e.g. polycrystalline) is explicitly contemplated. The shell can have a mounting surface designed to be conformable to architects' and builders' design needs while at the same time offering the stability required to support monocrystalline panels safely. This conformity includes the planar geometry of the platform which may be a rectangle, a square, a circle or oval, a polygon, or an irregular shape, for example. FIGS. 4A-40 depict exemplary views of various topologies and surfaces for geometrically complex solar panels, in accordance with some embodiments

In some embodiments, the geometrically complex solar panels can be made of a conformable material such as aluminum, steel, acrylic, polycarbonate, wood, concrete, Plexiglas, or other suitable material that can be molded, stamped, carved, or otherwise shaped and which will be rigid in the end state. Thus, the shell may be described as a curved shield, a cone section, or may exhibit other curved surface design, or it may be flat. Generally speaking, the shell may be molded or otherwise formed into such shapes that will conform to the design goals of an architect or builder, which may include aesthetic considerations and/or considerations that can optimize the energy input of solar radiation as the sun moves across the sky.

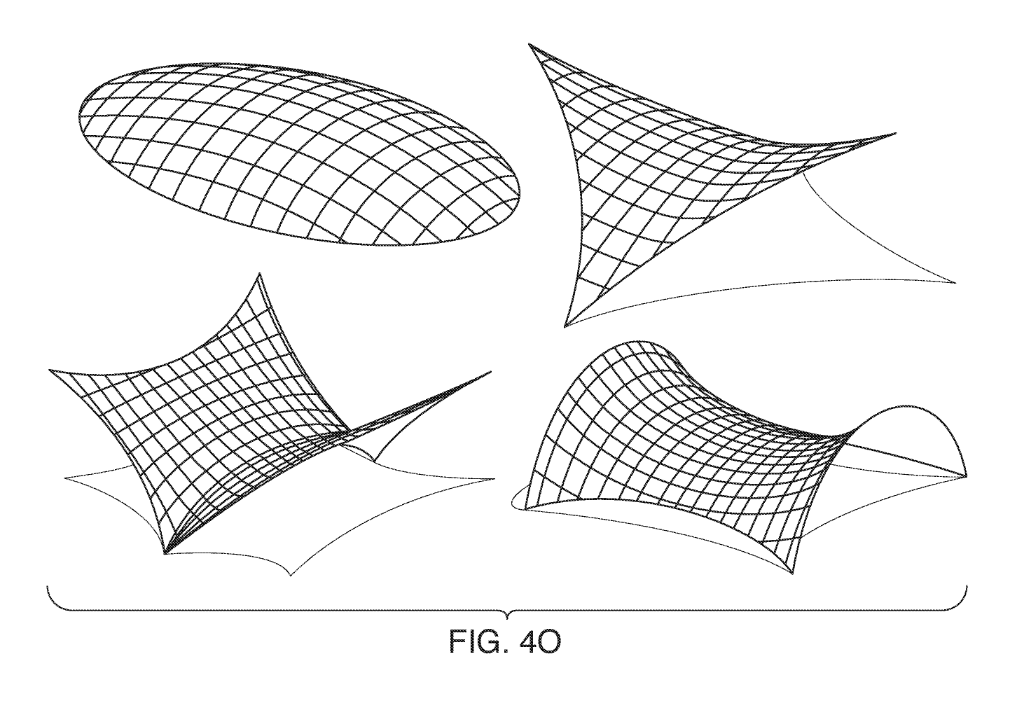

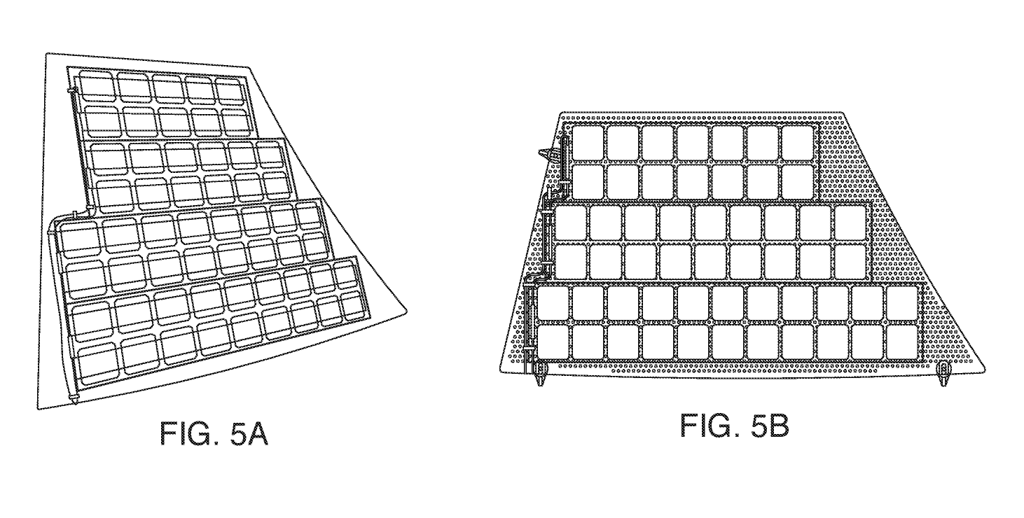

The geometrically complex solar panels may be formed with any arbitrary shape, such that its perimeter may be regular, linear, irregular or non-linear and its surface may be non-planar, planar or flat, singly curved, doubly curved, or irregularly curved. FIGS. 5A and 5B show perspective and elevation views of geometrically complex solar panels, in accordance with various embodiments.

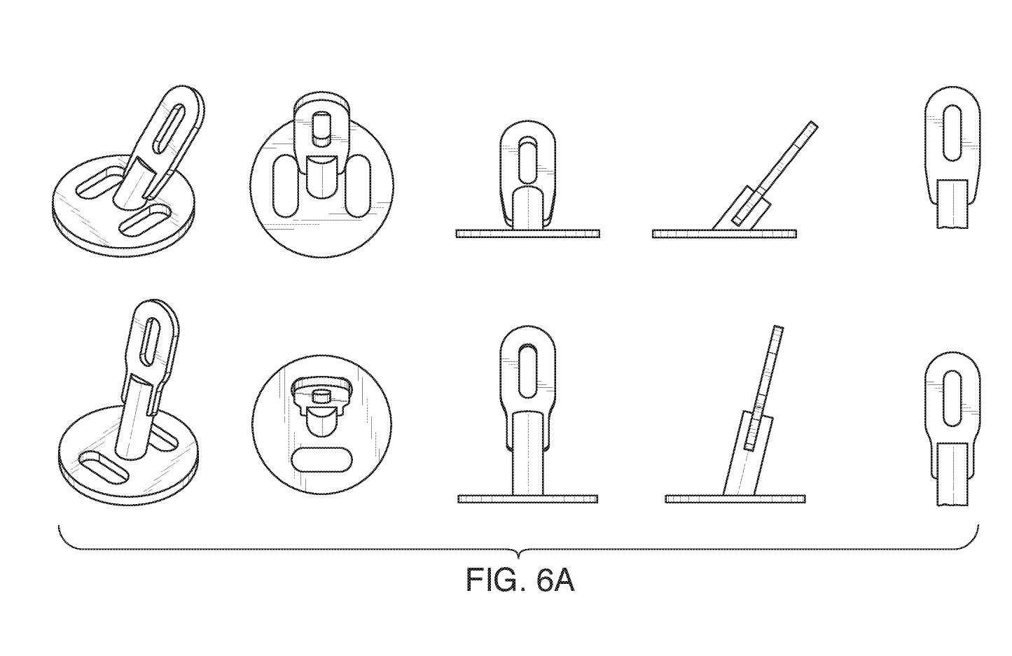

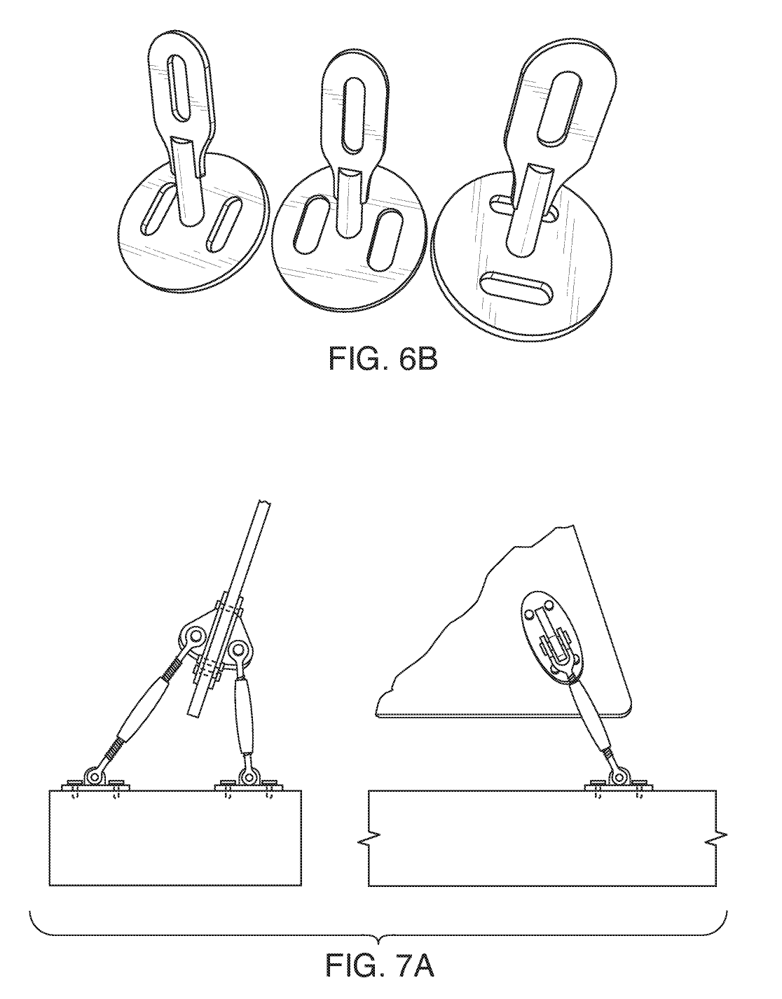

Reinforced point connections may be used to sustain the loads and stresses to which the geometrically complex solar panels may be exposed when mounted to a frame or other support facility. These point connections may enable the geometrically complex solar panels to float entirely or partially within a frame or other mounting structure. FIGS. 6A and 6B show exemplary schematic and perspective views of point connectors for geometrically complex solar panels, in accordance with various embodiments.

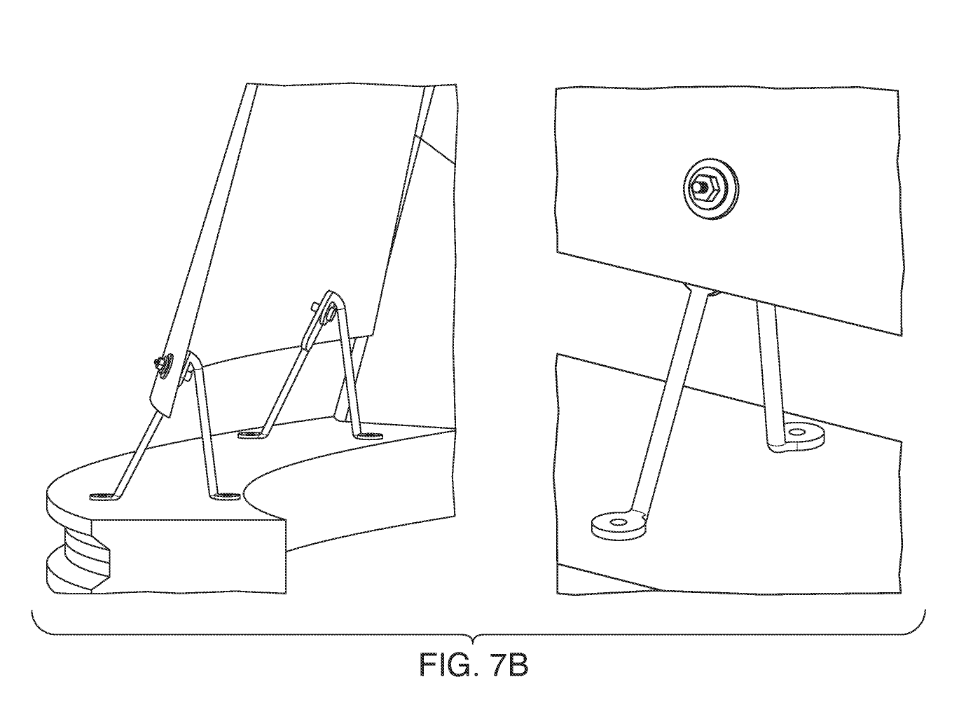

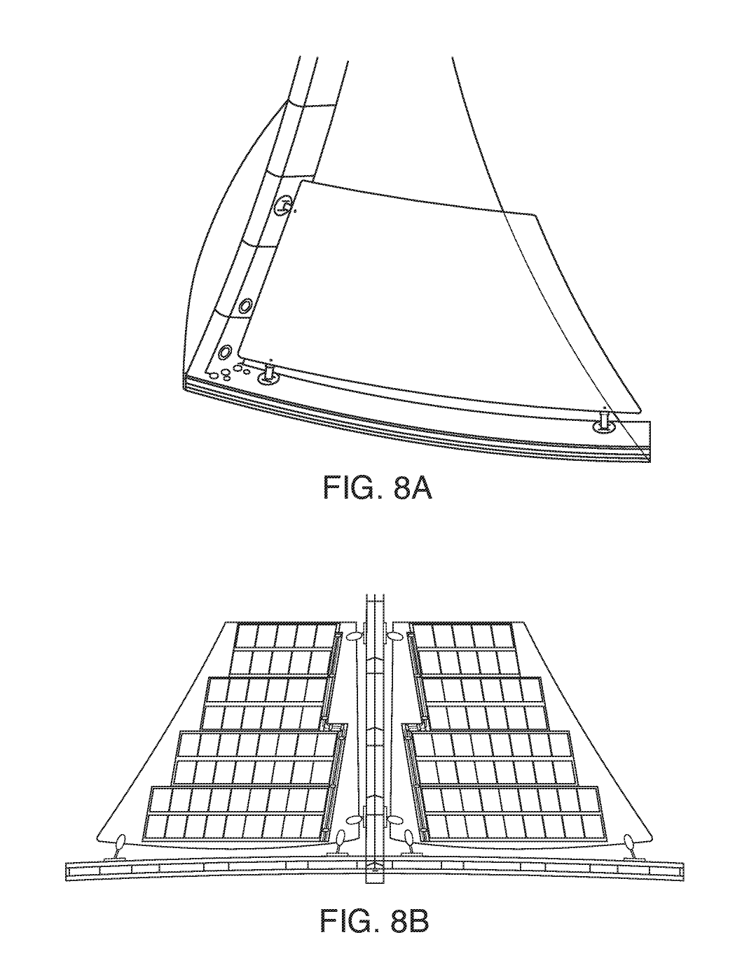

The geometrically complex solar panels may be may be mounted to either a horizontal or vertical surface (or any angle in between) whether the surface is planar or non-planar or otherwise irregular. Furthermore, the geometrically complex solar panels may be mounted in a perimeter frame. FIGS. 7A and 7B depict schematic and perspective views of point connections for geometrically complex solar panels, in accordance with some embodiments. FIGS. 8A and 8B depict schematic and elevation views of geometrically complex solar panel installations, in accordance with some embodiments.

Because the shell for a geometrically complex solar panel can be made to custom specifications, its various features may be conformed to both design and utility parameters for that particular design specification. Specifications for the shell may include, for example, that it be made of clear or translucent materials to allow for some light penetration into the building interior for some applications. The shell may also include perforations that allow light passage, which perforations or holes may also be arranged in patterns that are aesthetically and/or informatively meaningful. Such perforations or holes can also reduce wind loads and dissipate heat.

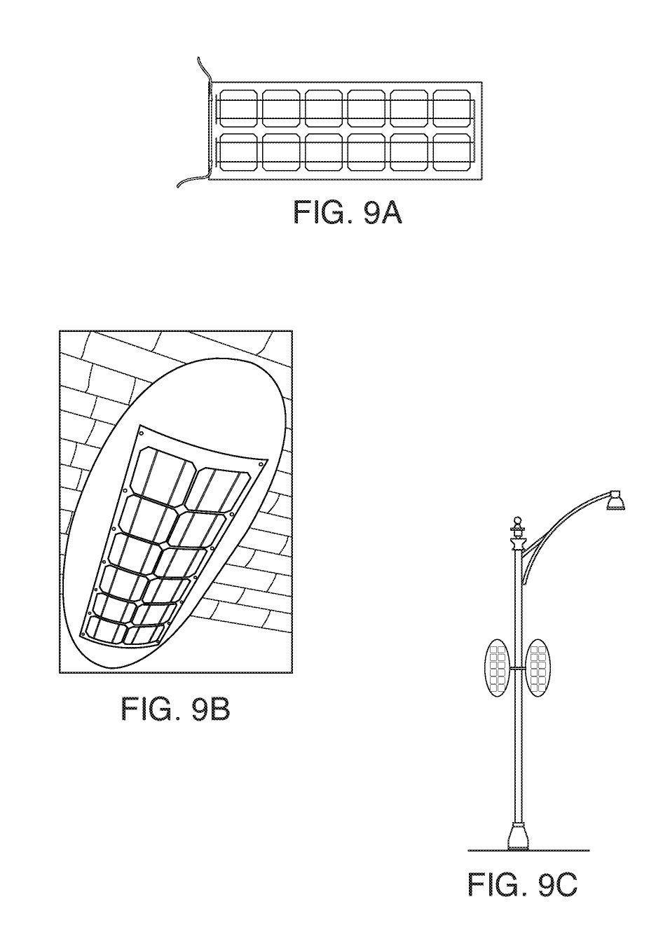

In some embodiments, the shell may be formed from a material that is receptive to the application of paint or dye or laminates or other means of coloration that decoratively, informatively or otherwise enhance the surface of the shell. FIGS. 9A-9C depict various views of assembly components for a decorated geometrically complex solar panel installation, in accordance with some embodiments.

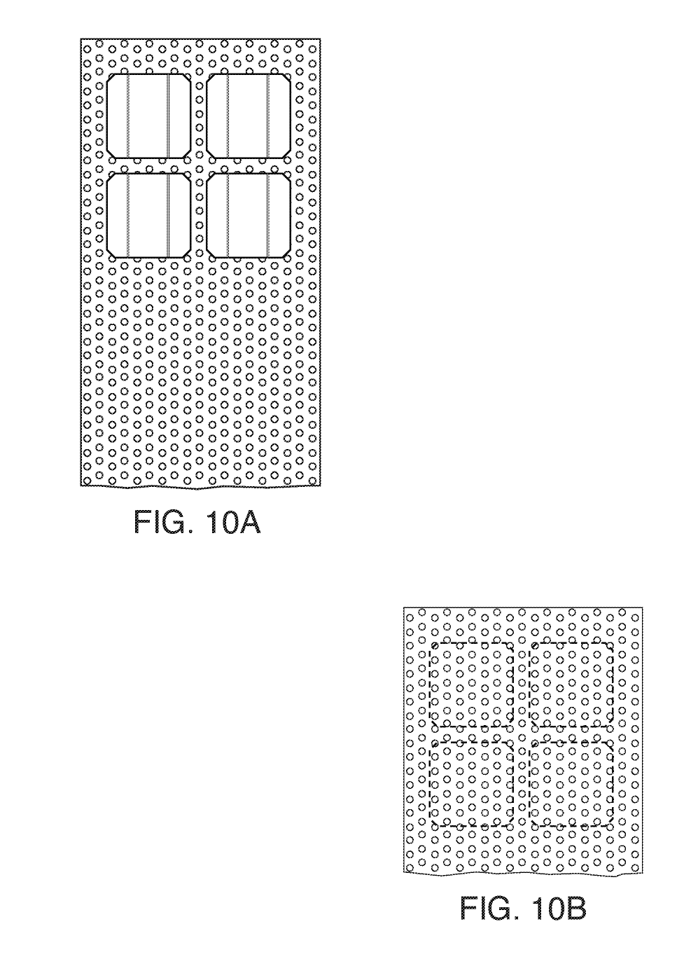

A method for assembling a geometrically complex solar panel may include applying die-cut adhesives that are approximately the same size and shape as the active cell area to adhere the module to a perforated material. Thus, an opaque adhesive can be used for adhesion without affecting light transmission through the areas of the perforated material not covered by modules. Once the module has been adhered to the perforated material, the tacky adhesive may be exposed to the environment through the perforations. Because this exposed adhesive could attract dirt, become unattractive, and potentially degrade the performance of the adhesive over time, the adhesive may be passivated by depositing a clear powder onto these exposed adhesive areas. FIGS. 10A and 10B front and back views of perforated geometrically complex solar panels, in accordance with some embodiments.

While there have been described methods and apparatus for structurally supporting geometrically complex solar modules using a rigid substrate and point support connections, it is to be understood that many changes may be made therein without departing from the spirit and scope of the invention. Insubstantial changes from the claimed subject matter as viewed by a person with ordinary skill in the art, no known or later devised, are expressly contemplated as being equivalently within the scope of the claims. Therefore, obvious substitutions now or later known to one with ordinary skill in the art are defined to be within the scope of the defined elements.

The described embodiments of the invention are presented for the purpose of illustration and not of limitation.

What is claimed is:

1. A geometrically complex solar module, comprising:
a rigid shell comprising a mounting surface, wherein the mounting surface comprises a curvature that is curved in at least one dimension;
at least one flexible solar module comprising a plurality of flexible monocrystalline solar cells, wherein the at least one flexible solar module is coupled to and follows the curvature of the mounting surface.

2. The geometrically complex solar module of claim 1, wherein the rigid shell is composed of a conformable material.

3. The geometrically complex solar module of claim 2, wherein the conformable material is chosen from the group consisting of aluminum, steel, acrylic, polycarbonate, wood, concrete, and Plexiglas™.

4. The geometrically complex solar module of claim 1, further comprising a plurality of holes extending through the rigid shell.

5. The geometrically complex solar module of claim 1, wherein the plurality of flexible monocrystalline solar cells is encased in ETFE.

6. A mounting system for geometrically complex solar panels, comprising:
a mounting member, comprising:
a base plate comprising at least two base apertures;
a post extending obliquely from an area of the base plate located between the two base apertures, the post comprising a distal end opposite the base plate, the distal end comprising a post aperture;
a rod-coupled at a first end to the post aperture; and
a lug plate coupled to a second end of the rod, opposite the first end.

7. The mounting system of claim 6, wherein the rod is non-rotatably coupled to the post aperture.

8. The mounting system of claim 7, wherein the rod is rotatably coupled to the post aperture.

9. The mounting system of claim 6, wherein the rod is length-adjustable.

10. The mounting system of claim 6, wherein the lug plate is configured to attach the mounting system to a rigid shell of a geometrically complex solar module.

11. The mounting system of claim 6, wherein the mounting member is configured to mount the mounting system of an installation surface.

12. The mounting system of claim 6, further comprising:
a second mounting member, comprising:
a second base plate comprising at least two base apertures;
a second post extending obliquely from an area of the second base plate located between the two base apertures, the second post comprising a distal end opposite the base plate, the distal end comprising a post aperture;
a second rod-coupled at a first end to the second post aperture; and
a second lug plate coupled to a second end of the second rod, opposite the first end.

13. The mounting system of claim 12, further comprising:
a geometrically complex solar panel coupled to the first lug plate and the second lug plate, the first and second mounting members supporting the geometrically complex solar panel above an installation surface.

14. A solar module, comprising:
a rigid shell comprising a mounting surface, wherein the mounting surface comprises a plurality of perforations formed therethrough;
at least one flexible solar module each comprising a plurality of flexible monocrystalline solar cells, wherein the at least one flexible solar module encases the pluratliy of flexible monocrystalline solar cells in a transparent material.

15. The solar module of claim 14, wherein the rigid shell is formed from aluminum.

16. The solar module of claim 14, wherein the transparent material is ETFE.
